(19) United States
(12) Patent Application Publication
(10) Pub. No.: US 2026/0196446 A1
(43) Pub. Date: Jul. 9, 2026

(54) Processing Apparatus and Processing Method

(71) Applicant: Tokyo Electron Limited, Tokyo (JP)

(72) Inventor: Toshifumi KITAHARA, Tokyo (JP)

(21) Appl. No.: 19/435,176

(22) Filed: Dec. 29, 2025

(30) Foreign Application Priority Data
Jan. 8, 2025 (JP) 2025-002905

(51) Int. Cl. H01J 37/32

(52) U.S. Cl. CPC H01J 37/32642; H01J 37/3244; H01J 2237/1502

(57) ABSTRACT

Provided is a processing apparatus comprising: a processing chamber; a stage configured to hold a substrate in the processing chamber or a first ring located at a periphery of the stage; a second ring spaced apart from the stage or the first ring by a gap and configured to divide the processing chamber into an upper space and a lower space; and an actuator connected to the second ring and configured to drive the second ring.

### CROSS-REFERENCE TO RELATED APPLICATIONS

This application claims priority to Japanese Patent Application No. 2025-002905 filed on January 8, 2025, the entire contents of which are incorporated herein by reference.

### TECHNICAL FIELD

The present disclosure relates to a processing apparatus and a processing method.

### BACKGROUND

For example, Japanese Laid-open Patent Publication No. 2021-114546 discloses a substrate processing apparatus in which a peripheral component of a stage is fixed to a processing chamber by a first positioning pin located close to a reference position when the peripheral component of the stage is installed in the processing chamber. A second positioning pin, which is positioned more distant from the reference position than the first positioning pin, is inserted into a second hole elongated along the direction of movement of the second positioning pin. With this configuration, when the processing chamber is switched from a non-heated state to a heated state, the displacement of the peripheral component of the stage can be suppressed to the movement amount of the first positioning pin, thereby reducing a displacement dimension.

### SUMMARY

The present disclosure provides a processing apparatus and a processing method capable of improving the uniformity of substrate processing.

In accordance with an aspect of the subject application, there is provided a processing apparatus comprising: a processing chamber; a stage configured to hold a substrate in the processing chamber or a first ring located at a periphery of the stage; a second ring spaced apart from the stage or the first ring by a gap and configured to divide the processing chamber into an upper space and a lower space; and an actuator connected to the second ring and configured to drive the second ring.

### BRIEF DESCRIPTION OF THE DRAWINGS

FIG. 1 is a cross-sectional view showing an example of a configuration of a processing apparatus according to one embodiment.

FIG. 2 is an enlarged view showing a periphery of a stage according to the first embodiment.

FIG. 3 is a plan view showing the periphery of the stage according to the first embodiment.

FIG. 4 is a plan view showing the periphery of the stage according to the first embodiment.

FIG. 5 is an enlarged view showing a periphery of a stage according to a second embodiment.

FIGS. 6A to 6C are plan views showing the periphery of the stage according to the second embodiment.

### DETAILED DESCRIPTION

Hereinafter, embodiments of the processing apparatus and processing method of the present disclosure will be described in detail with reference to the accompanying drawings. Further, the following embodiments are not intended to limit the processing apparatus and the processing method of the present disclosure, and can be appropriately combined without contradicting the configurations and the processing contents of the present disclosure. Further, the drawings to be referred to below are schematic for convenience of illustration. Therefore, details may be omitted, and the dimensional ratios in the drawings may not necessarily coincide with the actual ratios.

### Example of configuration of processing apparatus

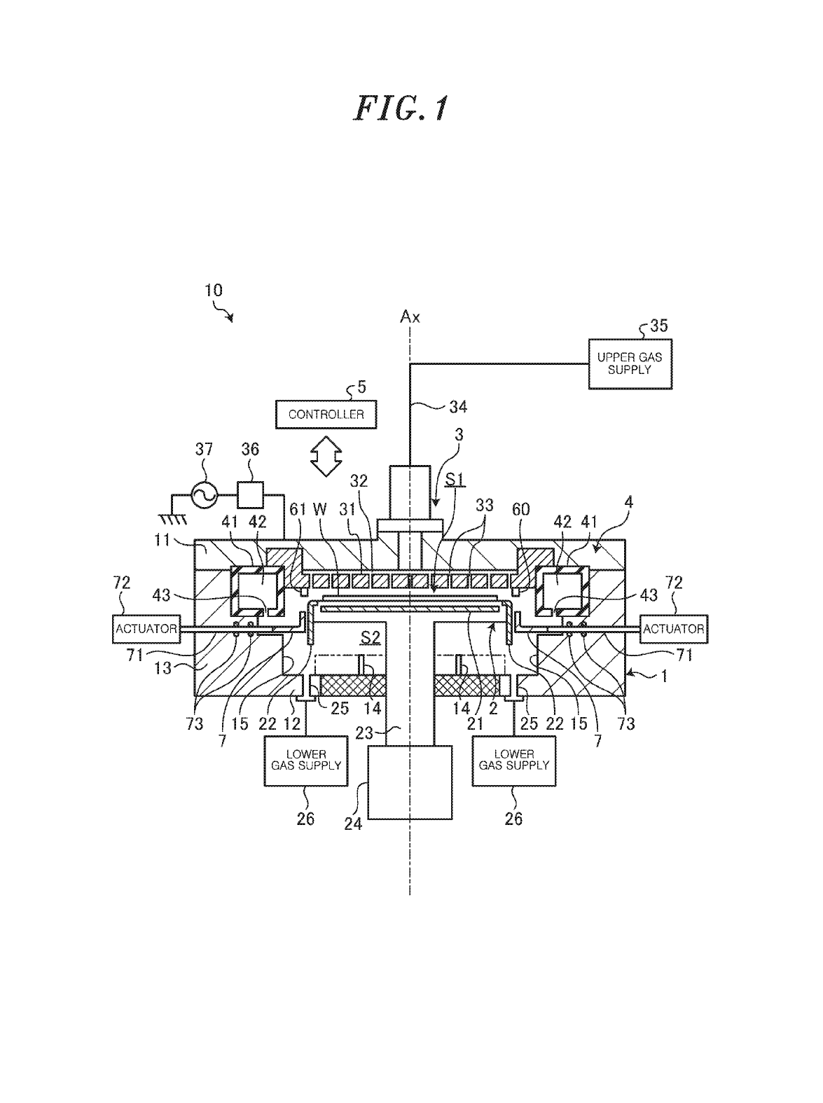

An example of a configuration of a processing apparatus 10 according to one embodiment will be described with reference to FIG. 1.

FIG. 1 is a cross-sectional view showing an example of a configuration of a processing apparatus 10 according to one embodiment.

The processing apparatus 10 may be an apparatus for performing film formation, such as chemical vapor deposition (CVD), on a substrate W, such as a semiconductor wafer, or may be an apparatus for performing etching. As shown in FIG. 1, the processing apparatus 10 includes a processing chamber 1, a stage 2, a gas supply mechanism 3, an exhaust mechanism 4, and a controller 5.

The processing chamber 1 is a vacuum chamber made of, e.g., aluminum, and an inner space thereof can be evacuated (depressurized). The processing chamber 1 has a ceiling wall 11, a bottom portion 12, and a sidewall 13 that connects the ceiling wall 11 and bottom portion 12. The sidewall 13 has a substantially cylindrical shape. The sidewall 13 has a loading/unloading port (not shown) for loading/unloading a substrate W between the processing chamber 1 and a transfer chamber adjacent to the processing chamber 1, and a gate valve (not shown) for opening and closing the loading/unloading port.

The stage 2 has a disc shape, and is made of, e.g., aluminum nitride in which a metal or a metal mesh electrode is embedded. The stage 2 also functions as a lower electrode. The stage 2 is supported by a support 23. The support 23 penetrates through the bottom portion 12 of the processing chamber 1 near the center of the bottom portion 12, and is fixed to a lifting mechanism 24. The stage 2 for holding the substrate W is provided at the top of the support 23. The support 23 may have an internal channel. The internal channel adjusts the temperature of the support 23 and the stage 2 by a heat transfer medium, such as cooling water, circulating therethrough.

At the bottom portion 12 of the processing chamber 1, three transfer pins 14, for example, are provided at positions corresponding to the stage 2. The stage 2 has through-holes (not shown) that define areas through which the transfer pins 14 pass. The solid line in FIG. 1 illustrates the stage 2 located at a processing position, and the dashed double-dotted line in FIG. 1 illustrates the stage 2 located at a transfer position. The processing position is the position where the substrate W is subjected to processing such as film formation, which will be described later. The transfer position is the position where the substrate W is transferred between the transfer chamber and the stage 2. The lifting mechanism 24 raises and lowers the stage 2 between the transfer position for the substrate W and the processing position for the substrate W by raising and lowering the stage 2. A heater 21 is embedded in the stage 2. The heater 21 is an example of a temperature control part that controls the temperature of the substrate W.

A gas supply mechanism 3 is provided above the stage 2 at the ceiling wall 11 of the processing chamber 1. The gas supply mechanism 3 includes a shower plate 31 facing the stage 2 and a gas flow space 32 formed between the ceiling wall 11 and the shower plate 31. A gas supply line 34 is connected to the ceiling wall 11. The upstream side of the gas supply line 34 is connected to an upper gas supply 35. The upper gas supply 35 may include, e.g., a source of a processing gas (reaction gas), a source of cleaning gas for removing a film deposited in the processing chamber 1, a flow rate controller, and the like. The upper gas supply 35 is an example of a processing gas supply that supplies a processing gas into the processing chamber 1. The shower plate 31 has a plurality of gas injection holes 33 penetrating therethrough in the thickness direction, and injects the processing gas in a shower-like manner toward the stage 2.

The shower plate 31 is connected to a radio frequency (RF) power supply 37 via a matcher 36. An RF power is applied from the RF power supply 37 between the shower plate 31 also functioning as an upper electrode and the stage 2 also functioning as a lower electrode, and plasma is generated from the processing gas supplied from the shower plate 31 to the processing space (hereinafter, also referred to as “upper space S1”) by capacitive coupling.

An exhaust mechanism 4 is provided at the sidewall 13 of the processing chamber 1, which surrounds the upper space S1, along the circumferential direction of the upper space S1. The exhaust mechanism 4 has an annular duct 41. The duct 41 is made of an insulating material. The duct 41 is fitted around the sidewall 13 of the upper space S1, thereby forming therein an annular flow passage 42 through which the processing gas discharged from the upper space S1 flows. Further, a plurality of exhaust holes 43 arranged in a ring shape as a whole are formed at the lower part of the duct 41. The exhaust holes 43 may be a plurality of holes, each having a circular shape in plan view, arranged in a circumferential direction. The exhaust holes 43 connect the flow passage 42 and the upper space S1. The duct 41 is connected to an exhaust port (not shown) at one location, and the exhaust port is connected to an exhaust device (not shown). The upper space S1 of the processing chamber 1 is evacuated from the exhaust port via the duct 41 by the exhaust device. Further, the exhaust hole 43 may be a single ring-shaped hole formed in the circumferential direction in plan view.

A flat shelf 15 surrounding the periphery of the stage 2 is formed under the duct 41. A partition ring 7 is installed at the shelf 15 to be spaced apart from the stage 2 located at the processing position and the outer ring 22 provided at the periphery of the stage 2 by a gap. The outer ring 22 is a ring-shaped member surrounding the outer periphery of the stage 2, and is made of ceramic. The partition ring 7 is a ring-shaped member that surrounds the periphery of the outer ring 22 (or the periphery of the stage 2 when the outer ring 22 is not provided) with a gap interposed therebetween, and is made of ceramic. Specifically, the outer ring 22 is a substantially cylindrical member that surrounds the outer periphery of the stage 2 and extends vertically downward to a position below the bottom surface of the stage 2. The partition ring 7 is positioned along the periphery of the outer ring 22 with a gap interposed therebetween. The inner circumferential surface of the partition ring 7 extends along the outer circumferential surface of the outer ring 22 to a position corresponding to the side surface of the stage 2.

The outer ring 22 is an example of a first ring located at the periphery of the stage 2. The partition ring 7 is an example of a second ring that is spaced apart from the stage 2 or the first ring located at the periphery of the stage 2 by a gap, and divides the inner space of the processing chamber 1 into an upper space S1 and a lower space S2.

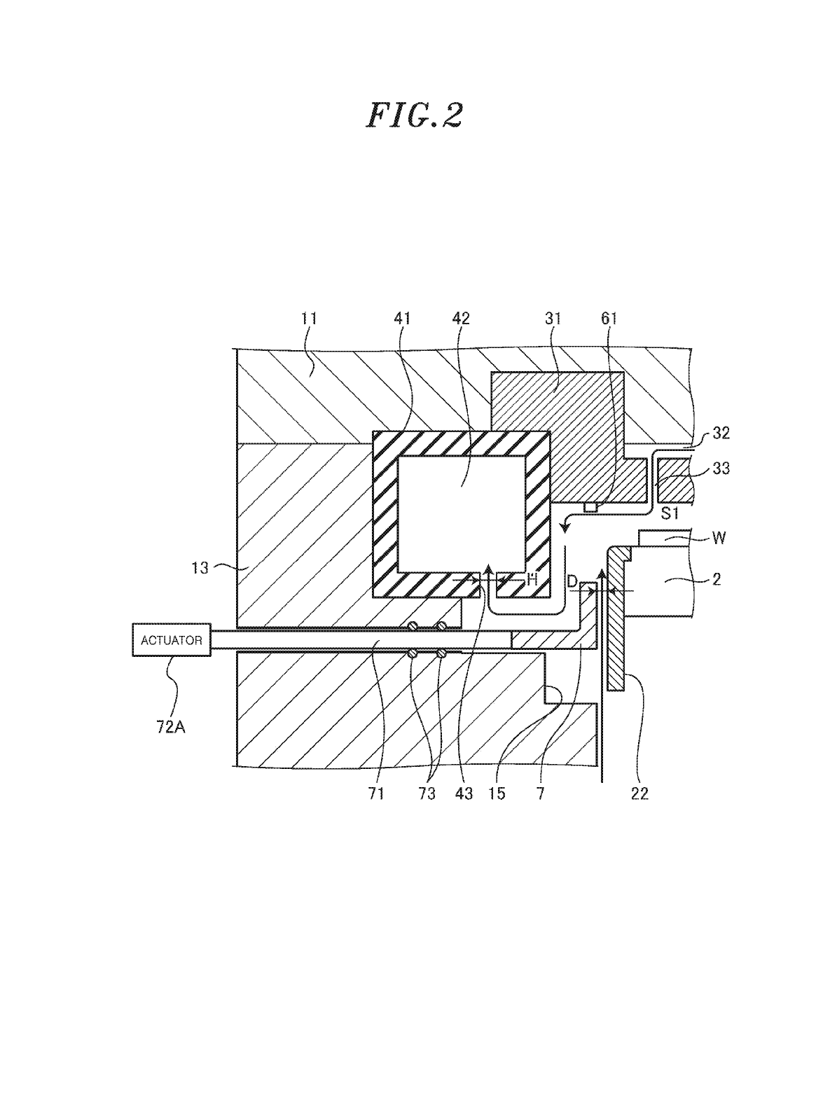

The partition ring 7 reduces a width of a gap D (see FIG. 2) formed between itself and the periphery of the stage 2 during the processing of the substrate W, thereby partitioning the upper space S1 and the lower space S2. Further, a sufficient gap is secured between the outer circumferential surface of the partition ring 7 and the sidewall 13 of the processing chamber 1. Therefore, the outer circumferential surface of the partition ring 7 is not in contact with the sidewall 13. The space between the outer circumferential surface of the partition ring 7 and the sidewall 13 of the processing chamber 1 is an annular recess. The plurality of exhaust holes 43 are exhaust ports that are opened in an annular shape toward the space.

An actuator 72 is provided on the outer circumferential surface of the partition ring 7 via a rod-shaped member 71. The rod-shaped member 71 penetrates through the sidewall 13 laterally, and is connected to the actuator 72 outside the processing chamber 1. The actuator 72 drives the partition ring 7. Three or more rod-shaped members 71 and three or more actuators 72 may be provided in the circumferential direction of the partition ring 7. The rod-shaped members 71 and the actuators 72 may be arranged at equal intervals in the circumferential direction of the partition ring 7. The number of the rod-shaped members 71 and the number of the actuators 72, which are provided in the circumferential direction of the partition ring 7, may be within a range of three to twelve. In the example of FIG. 1, an even number of rod-shaped members 71 and an even number of actuators 72, which are four or more, are provided.

During the processing of the substrate W, the stage 2 may reach a high temperatures of 300°C or more. Thus, the partition ring 7 may reach a temperature of up to about 300°C. Hence, the rod-shaped members 71 that connect the partition ring 7 and the actuators 72 are made of a ceramic or a metal that can withstand a high temperature of about 300°C.

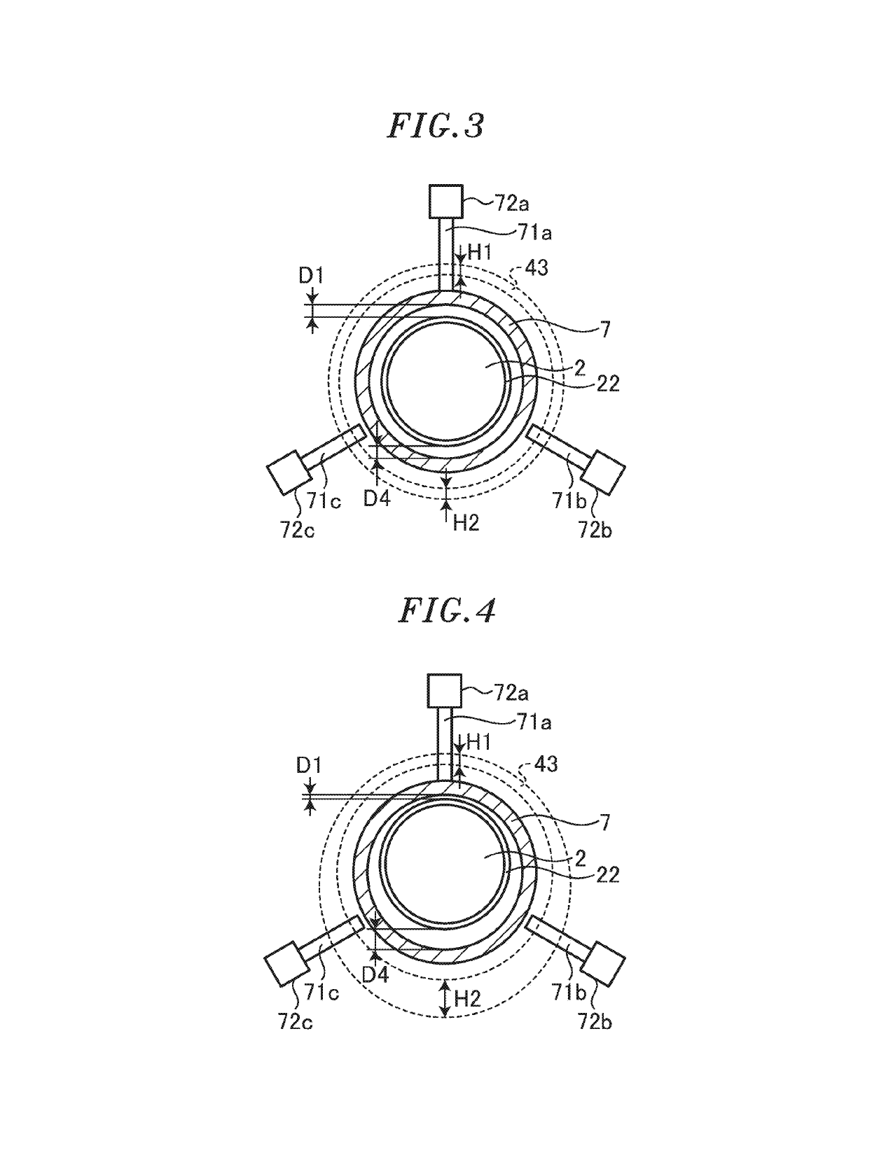

Three or more rod-shaped members 71 are provided in one-to-one correspondence with three or more actuators 72 (see FIG. 3). The actuators 72 pushes or pulls the corresponding rod-shaped members 71 to move the partition ring 7. A double O-ring 73, which is an example of a sealing member for preventing atmospheric air from entering the vacuum (depressurized) environment in the processing chamber 1, is provided at the outer periphery of each rod-shaped member 71. Each rod-shaped member 71 may be provided with a mechanical stop mechanism, such as a protrusion or the like, which limits the radial movement range of each rod-shaped member 71 to prevent the partition ring 7 from being in contact with the outer ring 22.

The lower gas supply 26 supplies a purge gas (hereinafter, also referred to as "bottom purge gas"), such as nitrogen gas or the like, from the bottom portion 12 of the processing chamber 1 to the lower space S2. The lower gas supply 26 allows the bottom purge gas to flow upward from the lower space S2 toward the upper space S1 through the annular gap D between the partition ring 7 and the outer ring 22. The lower gas supply 26 may be provided for each gas supply hole 25 provided at the bottom portion 12. One lower gas supply 26 may supply the bottom purge gas from a plurality of gas supply holes 25.

The processing apparatus 10 may have a sensor that detects the size of the gap D. At least three sensors are provided at positions corresponding to the circumferential direction of the gap D. In the example of FIG. 1, among three or more sensors, two sensors 60 and 61 are shown.

The controller 5 processes computer-executable instructions that cause the processing apparatus 10 to perform various steps described in the present disclosure. The controller 5 may be configured to control individual components of the processing apparatus 10 to perform various steps described herein. In one embodiment, the controller 5 may be partially or entirely included in the processing apparatus 10. The controller 5 may be realized by a computer, for example. The controller 5 may include a processing part, a memory, and a communication interface. The functions performed by the processing part described in the present disclosure may be implemented by circuitry or processing circuitry including a general-purpose processor, an application-specific processor, an integrated circuit, an application-specific integrated circuit (ASIC), conventional circuitry, and/or any combination thereof, which is programmed to perform the described functions. The processor is considered as circuitry or processing circuitry including a transistor and other circuitry. The processor may be a programmed processor that executes a program stored in the memory. This program may be stored in the memory in advance, or may be acquired via a medium when needed. The acquired program is stored in the memory, and read from the memory and executed by the processing part. The medium may be various computer-readable storage media, or may be a communication line connected to the communication interface. The memory may include a random access memory (RAM), a read only memory (ROM), a hard disk drive (HDD), a solid state drive (SSD), or any combination thereof. The communication interface may communicate with the processing apparatus 10 via a communication line such as a local area network (LAN) or the like. In the present disclosure, circuitry, unit, or means is hardware programmed to realize or configured to execute the described function. The hardware may be any hardware described in the present disclosure or any hardware programmed to realize or known to execute the described function. If the hardware is a processor, which is considered as a circuitry type, the circuitry, the means, or the unit is a combination of hardware and software used to configure the hardware and/or the processor.

### First embodiment

An example of processing performed by the processing apparatus 10 according to the first embodiment will be described with reference to FIGS. 1 and 2. FIG. 2 is an enlarged view showing the periphery of the stage 2 according to the first embodiment. In the processing apparatus 10 according to the first embodiment, an actuator 72A is used as an example of the actuator 72 shown in FIG. 1. The other configurations of the processing apparatus 10 are the same. The actuator 72A is, e.g., a motor.

When a substrate W is loaded into the processing chamber 1 and held by the stage 2 at the transfer position indicated by the dashed double-dotted line in FIG. 1, the controller 5 raises the lifting mechanism 24 to lift the stage 2 to the processing position indicated by the solid line in FIG. 1. The controller 5 supplies the bottom purge gas, such as nitrogen gas or the like, from the lower gas supply 26 to the lower space S2. Further, the controller 5 controls the pressure in the processing chamber 1, and heats the substrate W using the heater 21. Then, the controller 5 supplies the processing gas, such as a film formation gas, from the upper gas supply 35 to the upper space S1, and supplies an RF power from the RF power supply 37. Accordingly, the processing such as film formation or the like is performed on the substrate W in the upper space S1 using plasma generated from the processing gas by the RF power.

During the processing of the substrate W, the processing gas is supplied in a shower-like manner to the substrate W on the stage 2 in the upper space S1 through the plurality of gas injection holes 33 of the shower plate 31. The processing gas flows outward across the surface of the substrate W, and then flows into the plurality of annular exhaust holes 43 opened at the bottom portion of the duct 41 located at the sidewall 13 and is exhausted. A radial width H (corresponding to the diameter) of the exhaust holes 43 shown in FIG. 2 may be uniform across all the exhaust holes 43. The width H of the exhaust hole 43 relatively close to the exhaust port may be less than the width H of the exhaust hole 43 relatively distant from the exhaust port.

The annular gap D between the outer ring 22 and the partition ring 7 is the radial distance between the outer circumferential surface of the substantially cylindrical outer ring 22 and the inner circumferential surface of the partition ring 7. The lower gas supply 26 allows a bottom purge gas, such as nitrogen gas or the like, to flow upward from the lower space S2 toward the upper space S1 through the annular gap D. Accordingly, the processing gas supplied from the shower plate 31 to the upper space S1 can be prevented from flowing into the lower space S2 below the stage 2 through the gap D. In other words, the processing gas flows to the flow passage 42 through the plurality of exhaust holes 43 arranged in an annular shape under the duct 41 and is exhausted from the exhaust port. Hence, the film formation under the stage 2, which occurs due to the leakage of plasma into the lower space S2 through the gap D, can be prevented.

When preset processing time for the substrate W elapses and the processing of the substrate W is completed, the controller 5 stops the supply of the processing gas and the RF power, adjusts the pressure in the processing chamber 1, and then controls the processed substrate W to be unloaded from the processing chamber 1.

The central axis Ax shown in FIG. 1 is an axis passing through the center of the processing chamber 1. In other words, the central axis Ax passes through the centers of the ceiling wall 11 and the bottom portion 12 of the processing chamber 1. When the central axis Ax coincides with the central axes of the stage 2, the outer ring 22, and the partition ring 7, the four parts, i.e., the processing chamber 1, the stage 2, the outer ring 22, and the partition ring 7 are arranged concentrically. In this case, the size of the gap D between the outer ring 22 provided at the periphery of the stage 2 and the partition ring 7 is the same at any position in the circumferential direction of the annular gap D. Therefore, the bottom purge gas is uniformly supplied from the lower space S2 to the periphery of the stage 2 in the upper space S1 through the gap D. When the bottom purge gas is supplied uniformly to the periphery of the stage 2 through the annular gap D, the exhaust of the processing gas from the duct 41 becomes uniform in the circumferential direction, and the thickness of the film formed on the substrate W becomes uniform in the circumferential direction, thereby improving the uniformity of the processing of the substrate W. In other words, when the bottom purge gas supplied to the periphery of the stage 2 through the gap D is non-uniform in the circumferential direction, the exhaust of the processing gas from the duct 41 becomes non-uniform in the circumferential direction, and the thickness of the film formed on the substrate W becomes non-uniform in the circumferential direction, which may result in deterioration of the uniformity of the processing of the substrate W. In other words, the circumferential non-uniformity of the bottom purge gas passing through the gap D affects the uniformity of the processing of the substrate W.

The circumferential non-uniformity of the bottom purge gas may also be affected by the position of the exhaust port, but is mainly determined by the relative positions of the four parts, i.e., the processing chamber 1, the stage 2, the outer ring 22, and the partition ring 7. If the position of the exhaust port is irrelevant, the circumferential non-uniformity the bottom purge gas is prevented by arranging the four parts concentrically, which makes the processing of the substrate W uniform. However, it is difficult to consistently ensure the concentric arrangement of the four parts due to the following reasons.

For example, during the processing of the substrate W, the stage 2 is raised to the processing position indicated by the solid line in FIG. 1. After the processing the substrate W, the stage 2 is lowered to the transfer position indicated by the dashed double-dotted line in FIG. 1. In this manner, the stage 2 is raised and lowered for processing of each substrate W. Whenever the stage 2 moves up and down, the gap D between the outer ring 22 and the partition ring 7 changes. From the above, it is clear that it is difficult to move the central axis of the stage 2 to coincide with the central axis Ax of the processing chamber 1, or to consistently ensure the concentric arrangement of the four parts. Accordingly, the gap D between the outer ring 22 and the partition ring 7 becomes non-uniform in the circumferential direction, which causes the circumferential non-uniformity of the bottom purge gas and results in poor processing uniformity of substrates W. This is particularly likely to occur in the processing apparatus 10 including the exhaust mechanism 4 in which a single exhaust port connected to the exhaust device is provided at the annular duct 41, and a gas is exhausted from the single exhaust port through the plurality of exhaust holes 43 (or annular (slit-shaped) exhaust holes) arranged in an annular shape and the annular flow passage 42.

In response to this, it is conceivable to improve the uniformity of the processing of the substrate W by rotating the stage 2 during the processing of the substrate W. However, in the case of providing a rotation mechanism at the stage 2, the temperature at which the stage 2 provided with the rotation mechanism can be used is limited, so that the substrate W may not be subjected to desired high-temperature processing (e.g., 650°C or higher). In addition, the manufacturing cost of the apparatus increases by providing a rotation mechanism at the stage 2.

As an alternative method, the inventors have conducted tests in which film formation was performed while changing the flow rate of the bottom purge gas. The test results showed that the increase in the flow rate of the bottom purge gas led to the improvement of the film thickness uniformity on the substrate W to some extent. However, only by controlling the flow rate of the bottom purge gas, it was difficult to improve a non-uniform circumferential film thickness on the substrate W. The test results also demonstrated the correlation between the circumferential thickness of the film formed on the substrate W and the circumferential non-uniformity of the bottom purge gas. Since the uneven film thickness is caused by the circumferential non-uniformity of the bottom purge gas, the film thickness uniformity can be improved without changing the flow rate of the bottom purge gas as long as the circumferential non-uniformity of the bottom purge gas can be controlled.

Therefore, in the processing apparatus 10, the circumferential non-uniformity of the bottom purge gas supplied through the gap D is corrected. Hence, in the processing apparatus 10, it is possible to improve the processing uniformity of the substrate W without providing a rotation mechanism at the stage 2.

### Method for correcting circumferential non-uniformity of bottom purge gas

Hereinafter, a method for correcting the circumferential non-uniformity of the bottom purge gas using the processing apparatus 10 will be described with reference to FIGS. 3 and 4. FIGS. 3 and 4 are plan views showing the periphery of the stage 2 according to the first embodiment. FIGS. 3 and 4 show an example in which three rod-shaped members 71 and three actuators 72A are provided. The number of rod-shaped members 71 and the number of actuators 72A may be at least three, and may be six or more. As the number of rod-shaped members 71 and the number of actuators 72A increase, the processing uniformly the substrate W can be improved.

In the example of FIGS. 3 and 4, the three actuators 72A are illustrated as actuators 72a, 72b, and 72c. Further, the three rod-shaped members 71 are illustrated as rod-shaped members 71a, 71b, and 71c. Further, in the example of FIGS. 3 and 4, components other than the stage 2, the outer ring 22, the partition ring 7, the rod-shaped members 71a, 71b, and 71c, and the actuators 72a, 72b, and 72c are not illustrated. Further, the positions and sizes of the plurality of exhaust holes 43 are indicated by dotted lines.

The actuator 72a is provided to correspond to the rod-shaped member 71a, and pushes the partition ring 7 from one direction (hereinafter, referred to as "first direction") in the case of dividing the outer circumference of partition ring 7 into three parts. The actuator 72b is provided to correspond to the rod-shaped member 71b, and pushes the partition ring 7 from another direction (hereinafter, referred to as "second direction") in the case of dividing the outer circumference of partition ring 7 into three parts. The actuator 72c is provided to correspond to the rod-shaped member 71c, and pushes the partition ring 7 from the other direction (hereinafter, referred to as "third direction") in the case of dividing the outer circumference of the partition ring 7 into three parts. However, the present disclosure is not limited thereto, and the actuators 72, 72b, and 72c may pull the partition ring 7 from the respective directions.

In the example shown in FIGS. 3 and 4, the case in which one of the actuators 72a, 72b, and 72c is driven is described. However, two or all of the actuators 72a, 72b, and 72c may be driven. In addition, in the example shown in FIGS. 3 and 4, the rod-shaped member 71a is in contact with the partition ring 7, whereas the rod-shaped members 71b and 71c are not in contact with the partition ring 7, in order to show that the actuator 72a among the actuators 72a, 72b, and 72c is in operation. However, the present disclosure is not limited thereto, and all of the actuators 72a, 72b, and 72c may be in contact with the partition ring 7.

The controller 5 controls at least one of the actuators 72a, 72b, and 72c to move the partition ring 7 and adjust the size of the gap D. Accordingly, the uniformity of processing, such as film thickness on the substrate W is improved. The controller 5 may also control at least one of the actuators 72a, 72b, and 72c to move the partition ring 7 such that the central axis of the partition ring 7 coincides with the central axis of the stage 2 or the outer ring 22. However, the control operation of the controller 5 is not limited thereto.

In the example shown in FIG. 3, the controller 5 supplies a current to the actuator 72a to control the actuator 72a, and pushes the outer circumference of the partition ring 7 from the first direction. In this case, the controller 5 does not supply a current to the actuators 72b and 72c. Therefore, the partition ring 7 is not pushed from the second direction and the third direction. Accordingly, the partition ring 7 moves in the first direction, and the size of the gap D is adjusted. For example, in the example shown in FIG. 3, the partition ring 7 moves such that the central axis thereof coincides with the central axis of the stage 2 or the outer ring 22. Hence, in the gap D, a gap D1 corresponding to the position pushed by the rod-shaped member 71a becomes the same as a gap D4 on the opposite side of the gap D1. As a result, the circumferential non-uniformity of the bottom purge gas is corrected, thereby improving the uniformity of processing, such as film thickness on the substrate W. Further, the controller 5 may control the actuators 72a, 72b, and 72c to cause the rod-shaped members 71a, 71b, and 71c to pull the partition ring 7 instead of pushing the partition ring 7.

In the following example shown in FIGS. 3 and 4, the plurality of exhaust holes 43 arranged in a ring shape and having a diameter corresponding to the width H are indicated by imaginary dotted lines. In actual cases, the plurality of exhaust holes 43 having a diameter corresponding to a dotted line width may be arranged at predetermined intervals within a dotted line frame. In the example shown in FIG. 3, the radial width H (corresponding to the diameter) of the exhaust holes 43 is constant around the entire circumference. For example, the radial width H1 of the exhaust hole 43 corresponding to the position of the rod-shaped member 71a is equal to the radial width H2 of the exhaust hole 43 located on the opposite side thereof. However, the radial width H of the exhaust holes 43 may vary in the circumferential direction. For example, the exhaust hole 43 shown in FIG. 4 is designed such that the width H1 is smallest and the width H2 of the exhaust hole 43 located on the opposite side thereof is greatest. In this case, the controller 5 may move the partition ring 7 such that the radial gap D1 corresponding to the exhaust hole 43 with the width H1 becomes smallest and the radial gap D4 corresponding to the exhaust hole 43 with the width H2 becomes greatest. Accordingly, in the processing apparatus 10, by designing the width H of the exhaust holes 43 and controlling the gap D, the circumferential non-uniformity of the bottom purge gas can be corrected, and the uniformity of processing on the substrate W can be improved.

The controller 5 may control the actuators 72a, 72b, and 72c to perform pseudo-rotation of the radial width distribution of the gap D. For example, the controller 5 may periodically drive the actuators 72a, 72b, and 72c in that order at different timings, thereby periodically pushing the rod-shaped members 71a, 71b, and 71c in that order to move the partition ring 7. Accordingly, the partition ring 7 is periodically pushed from three directions and, thus, the radial width distribution of the gap D in the circumferential direction is periodically changed. Hence, the circumferential non-uniformity of the bottom purge gas can be periodically corrected, and the uniformity of processing on the substrate W can be improved.

The sensors, including the sensor 61 shown in FIG. 2, are provided at positions on the bottom surface of the shower plate 31 which correspond to the gap D. However, the present disclosure is not limited thereto, and the sensors may be provided on at least one of the ceiling wall 11 and the bottom portion 12 of the processing chamber 1. The sensor is an example of a detector that detects the size of the gap D. Further, the sensor may be provided on the sidewall 13 of the processing chamber 1 to detect the size of the gap D by measuring the stepped portion formed by the partition ring 7 and the outer ring 22. Three or more detectors may be provided at positions corresponding to the circumferential direction of the partition ring 7. The controller 5 may control the movement of the partition ring 7 based on the size of the gap D detected by the sensor.

The movement of the partition ring 7 may be performed when the processing apparatus 10 is installed in a facility such as a factory, or during a trial operation of the processing apparatus 10. The movement of the partition ring 7 may also be performed before the loading of the substrate W or before the processing of the substrate W. The partition ring 7 may be moved during or after the processing of the substrate W based on the detection value from the sensor.

### Effects of first embodiment

In the first embodiment, the controller 5 controls the actuator 72A (the actuators 72a, 72b, and 72c) to move the partition ring 7 using the rod-shaped members 71a, 71b, and 71c. Accordingly, in the processing apparatus 10, the gap D between the partition ring 7 and the outer ring 22 can be adjusted. Hence, the circumferential non-uniformity of the bottom purge gas flowing through the gap D can be corrected, and the processing uniformity on the substrate W can be improved.

### Second embodiment

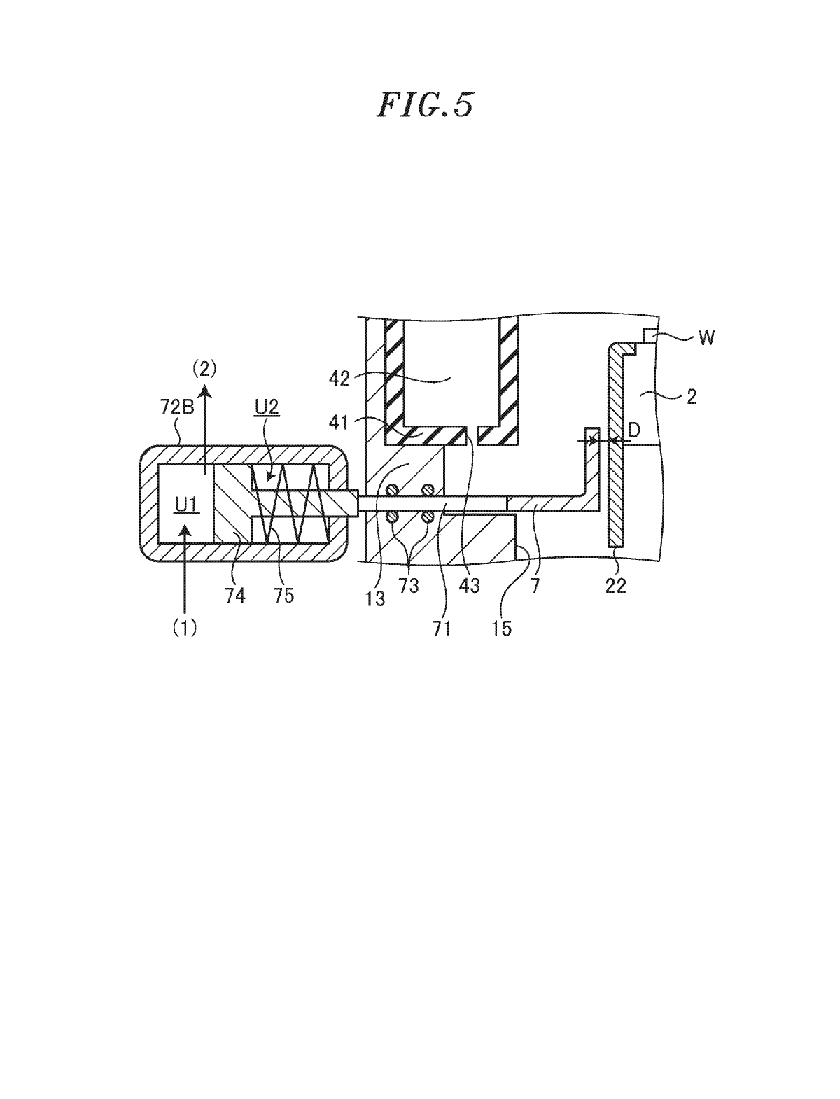

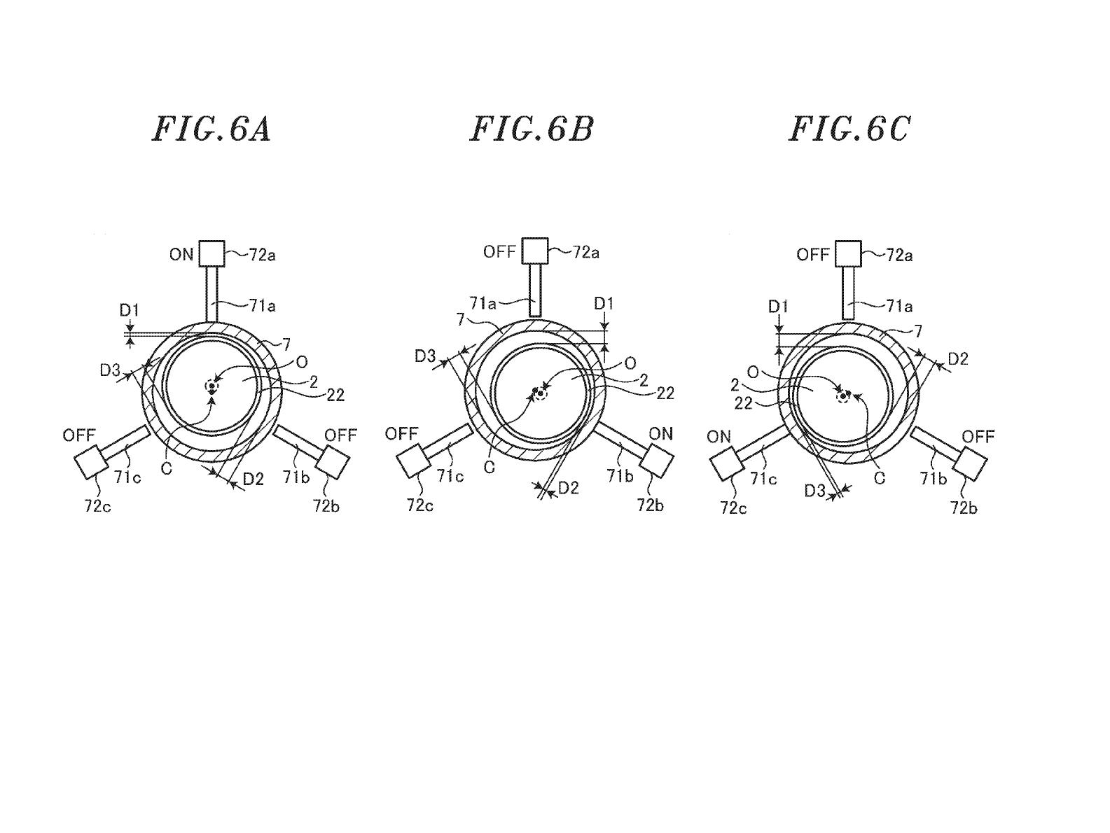

Next, an example of processing performed by the processing apparatus 10 according to a second embodiment will be described with reference to FIGS. 5 and 6A to 6C. FIG. 5 is an enlarged view showing the periphery of the stage 2 according to the second embodiment. FIGS. 6A to 6C are plan views showing the periphery of the stage 2 according to the second embodiment.

As shown in FIG. 5, in the processing apparatus 10 according to the second embodiment, an actuator 72B is used as an example of the actuator 72 shown in FIG. 1. The actuator 72B may be a solenoid actuator having an electromagnetic valve that opens and closes a valve element using attractive force of an electromagnet. Alternatively, the actuator 72B may be a pneumatic actuator that opens and closes a valve element by supplying and exhausting compressed air as fluid to be controlled. Hereinafter, the configuration and operation of the actuator 72B that is a pneumatic actuator will be described.

The actuator 72B is provided on the outer circumferential surface of the partition ring 7 via the rod-shaped member 71. The rod-shaped member 71 penetrates through the sidewall 13 laterally, and is connected to the actuator 72B outside the processing chamber 1. The actuator 72B moves the partition ring 7 by pushing and pulling the rod-shaped member 71. Three or more rod-shaped members 71 and three or more actuators 72B may be provided in the circumferential direction of the partition ring 7. The rod-shaped members 71 and the actuators 72B may be arranged at equal intervals in the circumferential direction of the partition ring 7. The number of rod-shaped members 71 and the number of actuators 72B arranged in the circumferential direction of the partition ring 7 may be within a range of three to twelve.

The actuator 72B has a piston 74 and a spring 75 inside a hollow housing. The piston 74 divides the inner space of the housing into spaces U1 and U2. Compressed air or air medium is supplied to the space U1 from the outside. On the space U2 side, a spring 75 is provided between the piston 74 and the housing. The piston 74 penetrates through the housing, and is connected to the rod-shaped member 71.

The controller 5 controls the actuator 72B. The controller 5 supplies a medium such as compressed air to space U1 (see FIG. 5 (1)). The piston 74 is pressed by the medium to compress the spring 75, so that the rod-shaped member 71 is pushed out by the force of the spring 75. As a result, the partition ring 7 moves to be pushed out at a position corresponding to the rod-shaped member 71.

When the controller 5 stops the operation of the actuator 72B, the supply of medium, such as compressed air, to space U1 is stopped, and the medium is discharged from the space U1 (see FIG. 5 (2)). Accordingly, the piston 74 returns to the space U1 by the force of the spring 75, and the rod-shaped member 71 is retracted. As a result, the partition ring 7 moves in a retracted manner at a position corresponding to the rod-shaped member 71. Further, in addition to the actuator 72B provided with the spring 75, the actuator that is driven only by the supply and discharge of air, or other common actuators can also be used.

In the examples of FIGS. 6A to 6C, the three actuators 72B are illustrated as the actuators 72a, 72b, and 72c. Further, the three rod-shaped members 71 are illustrated as the rod-shaped members 71a, 71b, and 71c. Further, in the examples of FIGS. 6A to 6C, components other than the stage 2, the outer ring 22, the partition ring 7, the rod-shaped members 71a, 71b, and 71c, and the actuators 72a, 72b, and 72c are not illustrated. It is assumed that the outer ring 22 and the partition ring 7 are arranged concentrically. For example, in the initial state, the gap D, i.e., the gaps D1, D2, and D3 corresponding to the rod-shaped members 71a, 71b, and 71c have the same size.

The controller 5 controls one of the actuators 72a, 72b, and 72c in an adjacent order to move the partition ring 7 and adjust the size of gap D. The controller 5 supplies a medium to the space U1 of one of the actuators 72a, 72b, and 72c indicated as "ON." The controller 5 does not supply a medium to the space U1 of the actuator indicated as “OFF” among the actuators 72a, 72b, and 72c and discharges the medium from the space U1.

In FIG. 6A, the controller 5 controls the actuator 72a to be "ON" and the actuators 72b and 72c to be "OFF." Accordingly, the rod-shaped member 71a is pushed out, and the size of the gap D1 corresponding to the rod-shaped member 71a becomes less than the sizes of the gaps D2 and D3 corresponding to the rod-shaped members 71b and 71c.

After a predetermined time elapses, as shown in FIG. 6B, the controller 5 controls the actuator 72b to be "ON" and the actuators 72a and 72c to be "OFF." Accordingly, the rod-shaped member 71b is pushed out, and the size of the gap D2 corresponding to the rod-shaped member 71b becomes less than the sizes of the gaps D1 and D3 corresponding to the rod-shaped members 71a and 71c.

After another predetermined time elapses, as shown in FIG. 6C, the controller 5 controls the actuator 72c to be "ON" and the actuators 72a and 72b to be "OFF." Accordingly, the rod-shaped member 71c is pushed out, and the size of the gap D3 corresponding to the rod-shaped member 71c becomes less than the sizes of the gaps D1 and D2 corresponding to the rod-shaped members 71a and 71b.

The controller 5 periodically repeats the operations shown in FIGS. 6A to 6C in that order. Accordingly, the controller 5 controls the actuators 72a, 72b, and 72c to move the partition ring 7 (perform pseudo-rotation of the distribution of the gap D), thereby changing the size of the gap D in the circumferential direction over time. For example, the controller 5 controls the actuators 72a, 72b, and 72c to periodically move the partition ring 7 such that the center C of the partition ring 7 rotates in the circumferential direction as indicated by the dotted lines in FIGS. 6A to 6C while being eccentric from the center O of the stage 2. By repeating the "ON" positions of the actuators 72a, 72b, and 72c in that order, the portion where the gap D is narrow periodically rotates in the circumferential direction over time. By performing pseudo-eccentric rotation of the partition ring 7 relative to the stage 2, the size of the gap D can be changed in the circumferential direction over time.

The controller 5 may control the actuator 72B to move the partition ring 7 based on the size of the gap D detected by the sensor. For example, in the processing apparatus 10, a plurality of sensors for detecting a state in which the stage 2 or the outer ring 22 and the partition ring 7 approach within a certain distance may be provided in the circumferential direction to correspond to the gap D. Then, the controller 5 may control the position where the stage 2 or the outer ring 22 and the partition ring 7 approach within a certain distance to rotate in the circumferential direction based on the detection results of the plurality of sensors.

Since the controller 5 drives any one of the actuators 72a, 72b, or 72c, the radial width distribution of the gap D changes periodically in the circumferential direction, thereby performing pseudo-rotation of the radial width distribution of the gap D. Accordingly, the circumferential non-uniformity of the bottom purge gas is corrected, thereby improving the uniformity of processing on the substrate W. In addition, the manufacturing cost can be reduced by using the actuator 72B that is less expensive than a motor.

The controller 5 may perform the operations shown in FIGS. 6A to 6C in the order of FIGS. 6A, 6B, and 6C, or in the order of FIGS. 6A, 6C, and 6B. Further, the controller 5 may start control from any one of FIGS. 6A, 6B, and 6C. Hence, the gap D between the partition ring 7 and the outer ring 22 can periodically vary in a clockwise direction or a counterclockwise direction. Due to the pseudo-rotation of the amount of bottom purge gas flowing through the gap D, it is possible to improve the uniformity of processing of the substrate W without rotating the stage 2.

The controller 5 may switch the timing of turning "ON" one of the actuators 72a, 72b, and 72c every 2 to 3 seconds, for example. For example, after the actuator 72a is turned "ON," the actuator 72a may be turned "OFF" and the actuator 72b may be turned "ON.". Then, after two seconds, the actuator 72b may be turned "OFF" and the actuator 72c may be turned "ON." By optimizing the switching timing, the controller 5 can more effectively improve the uniformity of processing of the substrate W without rotating the stage 2.

Further, the operation in which the controller 5 periodically repeats the processes shown in FIGS. 6A to 6C in that order to change the size of the gap D in the circumferential direction over time may be performed at least while the substrate W is being processed. Further, this operation may be performed during a period in which the substrate W is not processed.

### Actions and effects of second embodiment

In the second embodiment, the controller 5 controls the actuator 72B (the actuators 72a, 72b, and 72c) to repeatedly push the partition ring 7 sequentially in three directions using the rod-shaped members 71a, 71b, and 71c. Accordingly, in the processing apparatus 10, the size of the gap D between the partition ring 7 and the outer ring 22 changes in the circumferential direction. Hence, the circumferential non-uniformity of the bottom purge gas flowing through the gap D is corrected over time, thereby improving the uniformity of processing on the substrate W.

Further, by sequentially switching the actuators 72a, 72b, and 72c to be "ON," the narrow portion of the gap D periodically rotates. Due to the pseudo-eccentric rotation of the partition ring 7 relative to the stage 2, the size of the gap D periodically changes in the circumferential direction over time. Hence, the circumferential non-uniformity of the bottom purge gas flowing through the gap D is corrected over time, thereby further improving the uniformity of processing on the substrate W.

In the first and second embodiments, the method for adjusting the gap D between the outer ring 22 and the partition ring 7 has been described, but the present disclosure is not limited thereto. If the outer ring 22 is not provided at the periphery of the stage 2, the gap D between the stage 2 and the partition ring 7 may be adjusted using the method for correcting the circumferential non-uniformity of the bottom purge gas shown in the first and second embodiments.

### Processing method

As described above, the method (processing method) for correcting the circumferential non-uniformity of bottom purge gas is performed in the processing apparatus 10 including the processing chamber 1, the stage 2 that holds the substrate W in the processing chamber 1 and has a temperature control part that adjusts the temperature of the substrate W or the first ring (e.g., the outer ring 22) located at the periphery of the stage 2, the processing gas supply (e.g., the upper gas supply 35) that supplies the processing gas into the processing chamber 1, the second ring (e.g., the partition ring 7) that is spaced apart from the stage 2 or the first ring by the gap D and divides the processing chamber 1 into the upper space S1 and the lower space S2, and the actuator 72 that is connected to the second ring and that drives the second ring.

Further, the processing method includes: (A) placing the substrate W on the stage 2; (B) setting the substrate W to a predetermined processing temperature using the temperature control part; and (C) supplying the processing gas from the processing gas supply to process the substrate W; and (D) driving the actuator 72 to move the second ring and adjust the gap D at least during the processing of the substrate W. Accordingly, the circumferential non-uniformity of the bottom purge gas flowing through the gap D can be corrected, and the processing uniformity on the substrate W can be improved.

### Other modifications

As described above, the processing apparatus 10 includes the duct 41 having the plurality of exhaust holes 43 arranged in a ring shape at the sidewall 13 of the upper space S1. In the step (D) of the processing method described above, the controller 5 may control the actuator 72 to move the second ring, thereby relatively controlling the size of the gap D depending on the exhaust amount from the plurality of exhaust holes 43 in the circumferential direction. For example, the radial width H (corresponding to the diameter) of the exhaust holes 43 shown in FIG. 2 may be designed to be uniform in the circumferential direction in which the exhaust holes 43 are arranged, as shown in FIG. 3, or may be designed to be non-uniform, as shown in FIG. 4. Further, the size of the gap D may be controlled based on the relative relationship between the width H and the gap D.

For example, if the exhaust port is located at a position corresponding to the rod-shaped member 71a in FIG. 4, the width H of the exhaust holes 43 may increase as the distance from the exhaust port increases, which may allow the gas to flow uniformly through the annular flow passage 42 of the duct 41. In this case, the width H1 of the exhaust hole 43 on the exhaust port side is smallest, and the width H2 of the exhaust hole 43 on the opposite side of the exhaust port is greatest. Further, the controller 5 may relatively control the gap D to correspond to the width H of the exhaust holes 43. For example, the controller 5 may relatively reduce the size of the gap D on the exhaust port side such that the value of the gap D1 relative to the width H1 (value corresponding to D1/H1) becomes the same as the value of the gap D4 relative to the width H2 (value corresponding to D4/H2). Accordingly, the circumferential non-uniformity of the bottom purge gas flowing through the gap D is corrected, thereby improving the processing uniformity on the substrate W.

Further, when the size and arrangement of the exhaust holes are determined without considering the position of the exhaust port, such as when the radial width H (corresponding to the diameter) of the exhaust holes 43 is uniform in the circumferential direction or when the arrangement density of the exhaust holes 43 is uniform, the controller 5 may control the size of the gap D itself in consideration of the position of the exhaust port. For example, the controller 5 may reduce the size of the gap D itself such that the gap D1 close to the exhaust port becomes smaller than the gap D4 distant from the exhaust port. Accordingly, the circumferential non-uniformity of the bottom purge gas flowing through the gap D is corrected, thereby improving the uniformity of processing on the substrate W.

In the step (D) of the processing method, the controller 5 may move the second ring to control the size of the gap D. Further, in the step (D) of the processing method, the controller 5 may perform pseudo-rotation of the distribution of the gap D to change the size of the gap D in the circumferential direction over time. The controller 5 may repeatedly perform pseudo-rotation of the distribution of the gap D to periodically change the size of the gap D.

The technique of the present disclosure is not necessarily applied to the processing apparatus 10 that processes a single substrate W placed on the single stage 2 provided in the processing chamber 1. For example, the technique of the present disclosure can be applied to a processing apparatus that simultaneously processes a plurality of substrates W. In such a processing apparatus, the technique of the present disclosure can be applied as long as a second ring capable of adjusting the gap D between itself and the stage 2 or the first ring located at the periphery of the stage 2 is provided.

Further, the movement of the partition ring 7 may be performed using an arm (not shown) capable of moving the partition ring 7 in a horizontal direction (perpendicular to the central axis Ax) and an actuator for driving the arm, instead of using the rod-shaped member 71 and the actuator 72. Accordingly, the controller 5 can adjust the gap D by controlling the actuator to horizontally move the arm two dimensionally. Hence, the circumferential non-uniformity of the bottom purge gas can be corrected, and the processing uniformity on the substrates W can be improved.

Further, the actuator 72A using a motor and the actuator 72B using compressed air or a solenoid actuator are examples of the actuator 72, and the actuator 72 is not limited thereto. For example, the actuator 72 may drive the rod-shaped member 71 using ultrasonic waves.

It should be noted that the above-described embodiments are illustrative in all respects and are not restrictive. In actual cases, the above-described embodiments can be implemented in various forms. Further, the above-described embodiments may be omitted, replaced, or changed in various forms without departing from the scope of the appended claims and the gist thereof.

Further, the following appendices are disclosed with respect to the above embodiments.

### APPENDIX

(1)

A processing apparatus comprising:

a processing chamber;

a stage configured to hold a substrate in the processing chamber or a first ring located at a periphery of the stage;

a second ring spaced apart from the stage or the first ring by a gap and configured to divide the processing chamber into an upper space and a lower space; and

an actuator connected to the second ring and configured to drive the second ring.

(2)

The processing apparatus of (1), wherein the actuator includes a plurality of actuator elements provided at three or more positions in a circumferential direction of the second ring.

(3)

The processing apparatus of (1) or (2), further comprising:

a controller configured to control the actuator,

wherein the controller controls the actuator to move the second ring and adjust the size of the gap.

(4)

The processing apparatus of (3), further comprising:

a detector configured to detect the size of the gap,

wherein the controller controls the actuator to move the second ring based on the size of the gap detected by the detector.

(5)

The processing apparatus of (4), wherein the detector includes a plurality of sensors provided at three or more positions corresponding to a circumferential direction of the second ring.

(6)

The processing apparatus of any one of (1) to (5), further comprising:

a lower gas supply configured to supply purge gas to the lower space,

wherein the lower gas supply allows the purge gas to flow from the lower space to the upper space through the gap.

(7)

A processing method performed in a processing apparatus,

wherein the processing apparatus includes:

a processing chamber;

a stage that is configured to hold a substrate in the processing chamber and has a temperature control part that controls a temperature of the substrate or a first ring located at the periphery of the stage;

a processing gas supply configured to supply a processing gas into the processing chamber;

a second ring spaced apart from the stage or the first ring by a gap and configured to divide the processing chamber into an upper space and a lower space; and

an actuator connected to the second ring and configured to drive the second ring,

the method comprising:

(A) placing the substrate on the stage;

(B) setting the substrate to a predetermined processing temperature by the temperature control part;

(C) supplying the processing gas from the processing gas supply to process the substrate; and

(D) driving the driving part to move the second ring and adjust the gap at least during the processing of the substrate.

(8)

The processing method of (7), wherein the processing apparatus further includes a controller configured to controls the actuator, and

in said (D), the controller controls the actuator to move the second ring and change the size of the gap in a circumferential direction over time.

(9)

The processing method of (8), wherein in said (D), the controller controls the actuator to move the second ring such that a center of the second ring rotates in the circumferential direction while being eccentric from the center of the stage, thereby changing the size of the gap in the circumferential direction over time.

(10)

The processing method of (8), wherein the processing apparatus further includes a duct having a plurality of exhaust holes arranged in a ring shape at a sidewall of the upper space of the processing chamber, and

in said (D), the controller controls the actuator to move the second ring and relatively control the size of the gap depending on exhaust amount from the plurality of exhaust holes.

(11)

The processing method of (10), wherein in said (D), the controller performs pseudo-rotation of the distribution of the gap to change the size of the gap in the circumferential direction over time.

(12)

The processing method of (11), wherein in said (D), the controller repeatedly performs pseudo-rotation of the distribution of the gap to periodically change the size of the gap.

(13)

The processing method of any one of (8) to (12), wherein the processing apparatus further includes three or more detectors provided at positions corresponding to the circumferential direction of the second ring and configured to detect the size of the gap, and

wherein in said (D), the controller controls the actuator to move the second ring based on the size of the gap detected by the three or more detectors.

1. A processing apparatus comprising:
a processing chamber;
a stage configured to hold a substrate in the processing chamber or a first ring located at a periphery of the stage;
a second ring spaced apart from the stage or the first ring by a gap and configured to divide the processing chamber into an upper space and a lower space; and
an actuator connected to the second ring and configured to drive the second ring.

2. The processing apparatus of claim 1, wherein the actuator includes a plurality of actuator elements provided at three or more positions in a circumferential direction of the second ring.

3. The processing apparatus of claim 1, further comprising:
a controller configured to control the actuator,
wherein the controller controls the actuator to move the second ring and adjust the size of the gap.

4. The processing apparatus of claim 3, further comprising:
a detector configured to detect the size of the gap,
wherein the controller controls the actuator to move the second ring based on the size of the gap detected by the detector.

5. The processing apparatus of claim 4, wherein the detector includes a plurality of sensors provided at three or more positions corresponding to a circumferential direction of the second ring.

6. The processing apparatus of claim 1, further comprising:
a lower gas supply configured to supply purge gas to the lower space,
wherein the lower gas supply allows the purge gas to flow from the lower space to the upper space through the gap.

7. A processing method performed in a processing apparatus,
wherein the processing apparatus includes:
a processing chamber;
a stage that is configured to hold a substrate in the processing chamber and has a temperature control part that controls a temperature of the substrate or a first ring located at the periphery of the stage;
a processing gas supply configured to supply a processing gas into the processing chamber;
a second ring spaced apart from the stage or the first ring by a gap and configured to divide the processing chamber into an upper space and a lower space; and
an actuator connected to the second ring and configured to drive the second ring,
the method comprising:
(A) placing the substrate on the stage;
(B) setting the substrate to a predetermined processing temperature by the temperature control part;
(C) supplying the processing gas from the processing gas supply to process the substrate; and
(D) driving the driving part to move the second ring and adjust the gap at least during the processing of the substrate.

8. The processing method of claim 7, wherein the processing apparatus further includes a controller configured to controls the actuator, and
in said (D), the controller controls the actuator to move the second ring and change the size of the gap in a circumferential direction over time.

9. The processing method of claim 8, wherein in said (D), the controller controls the actuator to move the second ring such that a center of the second ring rotates in the circumferential direction while being eccentric from the center of the stage, thereby changing the size of the gap in the circumferential direction over time.

10. The processing method of claim 8, wherein the processing apparatus further includes a duct having a plurality of exhaust holes arranged in a ring shape at a sidewall of the upper space of the processing chamber, and
in said (D), the controller controls the actuator to move the second ring and relatively control the size of the gap depending on exhaust amount from the plurality of exhaust holes.

11. The processing method of claim 10, wherein in said (D), the controller performs pseudo-rotation of the distribution of the gap to change the size of the gap in the circumferential direction over time.

12. The processing method of claim 11, wherein in said (D), the controller repeatedly performs pseudo-rotation of the distribution of the gap to periodically change the size of the gap.

13. The processing method of claim 8, wherein the processing apparatus further includes three or more detectors provided at positions corresponding to the circumferential direction of the second ring and configured to detect the size of the gap, and
wherein in said (D), the controller controls the actuator to move the second ring based on the size of the gap detected by the three or more detectors.
